(19) United States
(12) Patent Application Publication
(10) Pub. No.: US 2020/0137337 A1
(43) Pub. Date: Apr. 30, 2020

(54) SENSOR PIXEL AND IMAGE SENSORS COMPRISING THE SAME

(71) Applicant: Silicon Display Technology, Yongin-si (KR)

(72) Inventors: Jong Woo JIN, Seoul (KR); Jinhyeong Yu, Incheon (KR); Sung Soo Hong, Ansan-si (KR); Young Man Park, Gwangju-si (KR); Taehan Go, Seoul (KR); Soon Ho Choi, Yongin-si (KR); Youn Duck Nam, Suwon-si (KR)

(21) Appl. No.: 16/600,640

(22) Filed: Oct. 14, 2019

(30) Foreign Application Priority Data
Oct. 25, 2018 (KR) 10-2018-0128331

(51) Int. Cl. H04N 5/378

(52) U.S. Cl. CPC H04N 5/378; H01L 27/14612

(57) ABSTRACT

The present invention relates to a sensor pixel including: a first transistor for a light sensing; a second transistor including one terminal connected to one terminal of the first transistor and the other terminal to which a reset voltage is transmitted; a third transistor including a gate connected to one terminal of the first transistor and one terminal connected to the other terminal of the first transistor; and a fourth transistor connected between the other terminal of the third transistor and a data line.

### CROSS-REFERENCE TO RELATED APPLICATION

This application claims priority to and the benefit of Korean Patent Application No. 10-2018-0128331 filed in the Korean Intellectual Property Office on Oct. 25, 2018, the entire contents of which are incorporated herein by reference.

### BACKGROUND OF THE INVENTION

### (a) Field of the Invention

The present invention relates to a sensor pixel and an image sensor including the same.

### (b) Description of the Related Art

In a case of a passive pixel used in a conventional image sensor, light intensity or an exposure time should be sufficiently strong or long for light sensing. In addition, a speed of a light reaction of a light sensing TFT has a great influence on the light sensing.

In addition, a reset is required after reading a signal stored in the passive pixel. However, since a capacitor size of the passive pixel is large, it takes time for the reset, and a sensor frame rate may decrease due to the required time.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention is to provide a sensor pixel and an image sensor that may solve the problems caused by the conventional passive pixel.

A sensor pixel according to the present invention includes: a first transistor for light sensing; a second transistor including one terminal connected to one terminal of the first transistor and the other terminal to which a reset voltage is transmitted; a third transistor including a gate connected to one terminal of the first transistor and one terminal connected to the other terminal of the first transistor; and a fourth transistor connected between the other terminal of the third transistor and a data line.

The first transistor may be formed of amorphous silicon.

A capacitor for fixing a gate voltage of the third transistor may be further included.

The capacitor may include a parasitic capacitor of the third transistor, a first capacitor formed between a gate and one terminal of the third transistor, a second capacitor formed between the gate of the third transistor and the gate of the first transistor, a third capacitor formed between the gate of the third transistor and the other terminal of the second transistor, or at least two among the parasitic capacitor and the first to third capacitors.

The fourth transistor may be switched depending on a first gate signal, the second transistor may be switched depending to a second gate signal, and enable timing of the second gate signal may precede enable timing of the first gate signal.

An image sensor according to the present invention includes: a sensor panel including a plurality of sensor pixels, and a plurality of first gate lines, a plurality of second gate lines, and a plurality of data lines connected to the plurality of sensor pixels; a gate driving circuit supplying a plurality of first gate signals and a plurality of second gate signals corresponding to a plurality of first gate lines and a plurality of second gate lines; and a sensor signal readout circuit receiving a plurality of data signals from the plurality of sensor pixels through the plurality of data lines, wherein each of the plurality of pixel sensors is implemented by the above-described sensor pixel.

A phase difference may exist between the first gate signal and the second gate signal corresponding to the plurality of sensor pixels disposed in the same row.

The enable timing of the second gate signal may precede the enable timing of the first gate signal.

The gate driving circuit may include a first gate driving unit generating a plurality of first gate signal; and a second gate driving unit generating a plurality of second gate signals.

Through an exemplary embodiment, the sensor pixel and the image sensor including the same that are capable of solving problems of the conventional passive pixel may be provided.

### BRIEF DESCRIPTION OF THE DRAWINGS

FIG. 1 is a view showing an image sensor according to an exemplary embodiment.

FIG. 2 is a view showing a partial configuration of a gate driving circuit for generating a plurality of first gate signals according to an exemplary embodiment.

FIG. 3 is a view showing a partial configuration of a gate driving circuit for generating a plurality of second gate signals according to an exemplary embodiment.

FIG. 4 is a waveform diagram showing a plurality of first and second gate signals.

FIG. 5 is a view showing a sensor pixel according to an exemplary embodiment.

FIG. 6 and FIG. 7 are views showing an example of a sensor pixel according to another exemplary embodiment, respectively.

FIG. 8 is a view showing a conventional passive pixel.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. In order to clearly explain the present invention in the drawings, parts that are irrelevant to the description are omitted, and similar reference numerals indicate similar parts throughout the specification.

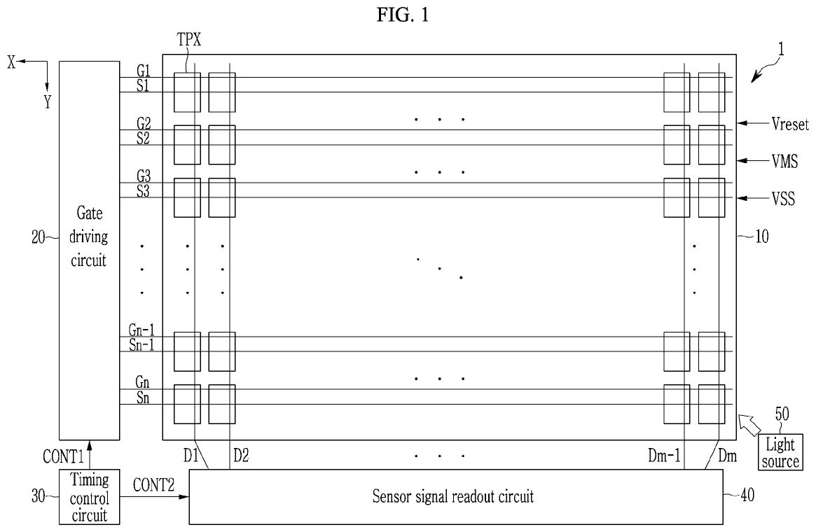

FIG. 1 is a view showing an image sensor according to an exemplary embodiment.

As shown in FIG. 1, an image sensor 1 includes a sensor panel 10, a gate driving circuit 20, a timing control circuit 30, a sensor signal readout circuit 40, and a light source 50.

The light source 50 provides light needed for optical fingerprint and character sensing. The light source 60 is disposed at the rear surface of the sensor panel 10 to provide the light to the front surface.

The sensor panel 10 includes a plurality of first gate lines S1-Sn, a plurality of second gate lines G1-Gn, a plurality of data lines D1-Dm, and a plurality of sensor pixels TPX.

A plurality of first gate lines S1-Sn and a plurality of second gate lines G1-Gn extend in a first direction (an X direction in FIG. 1) and are arranged along a second direction (a Y direction in FIG. 1) crossing the first direction.

Gate signals respectively corresponding to a plurality of sensor pixel rows are transmitted through a plurality of first gate lines S1-Sn. In synchronization with an enable level of the gate signal, a plurality of data voltages are transmitted from a plurality of sensor pixels supplied with the gate signal of the enable level to a plurality of data lines D1-Dm.

Reset control signals respectively corresponding to a plurality of sensor pixel rows are transmitted through a plurality of second gate lines G1-Gn. In synchronization with the enable level of the reset control signal, a plurality of sensor pixels supplied with the reset control signal of the enable level are initialized.

There is a phase difference between the first gate signal and the second gate signal supplied to the same sensor pixel row, and the second gate signal is enabled before or after the first gate signal, thereby initializing the sensor pixel.

A plurality of data lines D1-Dm extend in the second direction and are arranged along the first direction. Each data signal of a plurality of sensor pixels is transmitted to the sensor signal readout circuit 40 through a plurality of data lines D1-Dm.

A plurality of sensor pixels TPX are respectively connected to the corresponding first and second gate lines and data line, and a reset voltage Vreset, a light sensing control voltage VMS, and a driving voltage VSS are supplied to a plurality of sensor pixels TPX. Each of the sensor pixels TPX is initialized in synchronization with the corresponding second gate signal, and transmits the data signal to the corresponding data line in synchronization with the corresponding first gate signal.

The gate driving circuit 20 generates a plurality of first and second gate signals, and transmits them to a plurality of first gate lines S1-Sn and a plurality of second gate lines G1-Gn. The gate driving circuit 20 includes a plurality of shift registers, and the plurality of shift registers are respectively connected to the corresponding first and second gate lines.

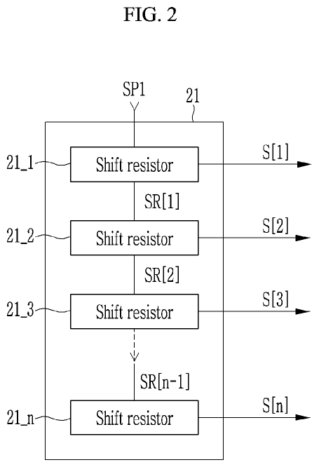

FIG. 2 is a view showing a partial configuration of a gate driving circuit for generating a plurality of first gate signals according to an exemplary embodiment.

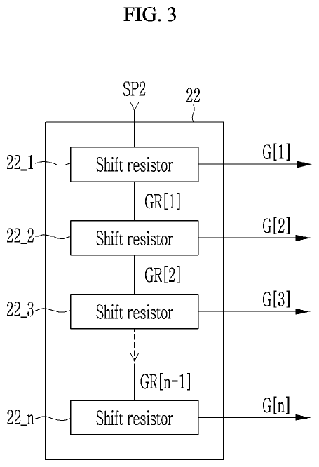

FIG. 3 is a view showing a partial configuration of a gate driving circuit for generating a plurality of second gate signals according to an exemplary embodiment.

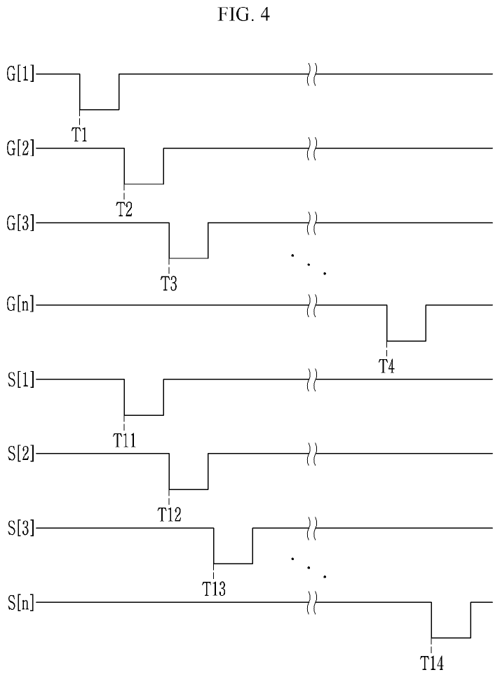

FIG. 4 is a waveform diagram showing a plurality of first and second gate signals.

The gate driving circuit 20 includes a first gate driving unit 21 and a second gate driving unit 22, the first gate driving unit 21 includes a plurality of shift registers 21_1-21_n, and the second gate driving unit 22 includes a plurality of shift registers 22_1-22_n.

As shown in FIG. 2, the shift register 21_1 receives and shifts a first start pulse SP1 by a predetermined period to generate a first gate signal S[1], and outputs the shift signal SR[1] in synchronization with the first gate signal S[1] to the next shift register 21_2.

The shift register 21_2 receives the shift signal SR[1] and shifts it by a predetermined period to generate the first gate signal S[2], and outputs the shift signal SR[2] in synchronization with the first gate signal S[2] to the next shift register 21_3.

The above operation is repeated, and the shift register 21_n receives the shift signal SR [n−1] and shifts it by a predetermined period to generate the first gate signal S [n].

In this case, the predetermined period may be one horizontal cycle, and each of the plurality of shift signals SR [1]-SR [n]) may be a signal in synchronization with the corresponding gate signal or the same signal as the corresponding gate signal.

As shown in FIG. 3, the shift register 23_1 receives the second start pulse SP2 and shifts it by a predetermined period to generate the second gate signal G [1], and then outputs the shifted signal GR[1] in synchronization with the second gate signal G [1] to the next shift register 22_2.

The shift register 22_2 receives the shift signal GR [1] and shifts it by a predetermined period to generate the second gate signal G [2], and then outputs the shift signal GR[2] in synchronization with the second gate signal G[2] to the next shift register 22_3.

This operation is repeated, and the shift register 22_n receives the shift signal GR [n−1] and shifts it by a predetermined period to generate the second gate signal G [n].

At this time, the predetermined period may be one horizontal cycle, and each of the plurality of shift signals GR [1]-GR [n]) is a signal in synchronization with the corresponding gate signal or the same signal as the corresponding gate signal.

In the description referring to FIG. 2 and FIG. 3, in the gate driving circuit 20, the first gate driving unit 21 and the second gate driving unit 22 are separately provided, but the invention is but not limited thereto.

The gate driving circuit 20 may include a plurality of gate driving units, the gate signal may be generated in each of a plurality of gate driving units, one among a plurality of generated gate signals may be supplied to the corresponding sensor pixel row as the second gate signal, and one having a predetermined period phase delay from the second gate signal among a plurality of gate signals may be supplied as the first gate signal to the corresponding sensor pixel row.

For example, a case in which the first gate signal has a phase delay of one horizontal cycle 1H from the second gate signal is described.

As shown in FIG. 4, there is a phase difference of 1H between the first and second gate signals supplied to the same pixel row, and in the exemplary embodiment, the second gate signals G[1]-G[n] are enabled earlier than the corresponding first gate signals S[1]-S[n] by one horizontal cycle 1H.

Specifically, the second gate signal G[1] increases to the high level which is an enable level at a time T1 and is maintained with the high level during an enable period. The first gate signal S[1] increases to the high level that is the enable level at the time T11 that is delayed from the time T1 by a predetermined period and is maintained with the high level during the enable period.

The second gate signal G [2]) rises to the high level which is the enable level at the time T2 and is maintained with the high level during the enable period. The first gate signal S[2] rises to the high level which is the enable level at the time T12 which is delayed by a predetermined period from the time T2 and is maintained with the high level during the enable period.

The second gate signal G[3] rises to the high level which is the enable level at the time T3 and is maintained with the high level during the enable period. The first gate signal S[3] rises to the high level that is the enable level at the time T13 which is delayed by a predetermined period from the time T3 and is maintained with the high level during the enable period.

A plurality of first and second gate signals are generated sequentially in this manner, the second gate signal G[n] rises to the high level that is the enable level at the time T4 and is maintained at the high level for the enable period, the first gate signal S[n] rises to the high level which is the enable level at the time T14 which is delayed by the predetermined period than the time T4 and is maintained with the high level during the enable period.

In an exemplary embodiment, the periods T1-T11, T2-T12, T3-T13, T4-T14, etc. may be periods corresponding to multiples of the horizontal cycle.

The description with reference to FIG. 2 to FIG. 4 is one example for explaining the gate driving circuit, but the present invention is not limited thereto. The gate driving circuit may only include one gate driving unit, the output of the i-th shift register among a plurality of shift registers may be the first gate signal, and the output of the (i−k) or (i+h)-th shift register may be the second gate signal. At this time, i, k, and h are integers of 1 or more.

Again referring to FIG. 1, the sensor signal readout circuit 40 may receive a plurality of data signals transmitted through a plurality of data lines D1-Dm and generate information for the detected fingerprint or character detected according to a plurality of data signals.

The timing control circuit 30 may generate control signals CONT1 and CONT2 required for controlling the operation of the gate driving circuit 20 and the sensor signal readout circuit 40.

The gate driving circuit 20 may generate a plurality of first and second gate signals according to the control signal CONT1. The sensor signal readout circuit 40 receives a plurality of data signals in synchronization with the timing when a plurality of data signals are transmitted through a plurality of data lines D1-Dm according to the control signal CONT2, and may perform signal processing required for generating information for the recognized fingerprint or character.

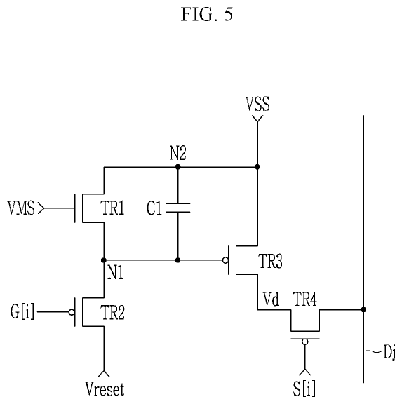

FIG. 5 is a view showing a sensor pixel according to an exemplary embodiment.

FIG. 5 shows the sensor pixel TPX disposed in the i-th row and j-th column. The sensor pixels TPX of the different positions include the same configuration as shown in FIG. 5, and the configurations may be connected as shown in FIG. 5.

The sensor pixels TPX include four transistors TR1-TR4 and a storage capacitor C1.

As shown in FIG. 5, the transistor TR1 is connected between a node N1 and a node N2, includes a gate to which a light sensing control voltage VMS is applied, and is formed of amorphous silicon. The capacitor C1 is connected between the node N1 and the node N2. The transistor TR3 includes one terminal connected to the node N2, the other terminal connected to one terminal of the transistor TR4, and the gate connected to the node N1. The transistor TR2 includes one terminal connected to the node N1, the other terminal to which the reset voltage Vreset is applied, and the gate to which the second gate signal G[i] is applied. The transistor TR4 is connected between the other terminal of the transistor TR3 and the data line Dj, and includes the gate to which the first gate signal S[i] is applied. As the driving voltage VSS is supplied to the node N2, one terminal voltage of the capacitor C1 connected to the node N2 is the driving voltage VSS and one terminal voltage of the transistor TR3 is also the driving voltage VSS. The light sensing control voltage VMS, the driving voltage VSS, and the reset voltage Vreset may be DC voltages supplied from the image sensor 1.

The transistor TR1 is a light sensing element that reacts to incident light, and may be implemented with an n-type amorphous silicon TFT. The transistor TR1 changes the gate voltage value of the transistor TR3 according to the reset voltage Vreset, the light sensing control voltage VMS, the driving voltage VSS, and the intensity and wavelength of the incident light.

The transistor TR2 is a reset switching TFT, and initializes the gate voltage value of the transistor TR3 into the reset voltage Vreset. The transistor TR2 is turned on to an on level (a low level) of the second gate signal G[i] and the reset voltage Vreset is applied to the node N1.

The transistor TR3 is a source follower TFT and may be implemented as a p-type polysilicon TFT. The transistor TR3 transfers a different voltage to the data line Dj according to the gate voltage.

The transistor TR4 is turned on by the on level (the low level) of the first gate signal S[i], thereby transmitting the voltage output from the transistor TR3 to the data line Dj.

The capacitor C1 fixes the gate voltage of the transistor TR3.

In FIG. 5, it is shown that the capacitor C1 is formed between the gate of the transistor TR3 and the node N2 to which the voltage VSS is supplied, but the present invention is not limited thereto.

Without forming a separate capacitor, the parasitic capacitor of the transistor TR3 may serve as a capacitor to fix the gate voltage of the transistor TR3.

Alternatively, the position of the capacitor C1 may be different from that shown in FIG. 5.

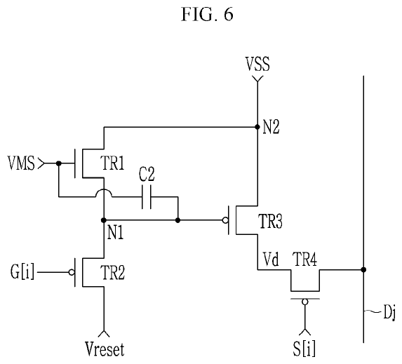

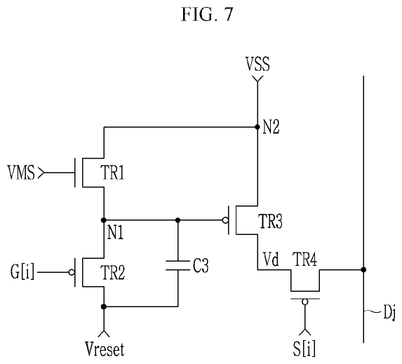

FIG. 6 and FIG. 7 are views showing an example of a sensor pixel according to another exemplary embodiment, respectively.

FIG. 6 and FIG. 7 are the views showing the pixel circuit depending on the various positions of the capacitor.

As shown in FIG. 6, the capacitor C2 may be formed between the gate of the transistor TR3 and the gate of the first transistor TR1.

As shown in FIG. 7, the capacitor C3 may be formed between the gate of the transistor TR3 and the other terminal of the transistor TR2.

Alternatively, the combination of the parasitic capacitor of the third transistor TR3 and at least two of the capacitors C1-C3 may be used to implement a capacitor that fixes the gate voltage of the third transistor TR3.

The operation of sensor pixels TPX is described as following.

First, the transistor TR3 may be turned off with the reset voltage Vreset and then be gradually turned on depending on the intensity and wavelength of the light.

For example, the second gate signal G[i] becomes the low level such that the transistor TR2 is turned on and the reset voltage Vreset is supplied to the node N1. Thus, the transistor TR3 is turned off. At this time, the reset voltage Vreset is a voltage belonging to a range of 0 V to 10 V, and for example, may be 3 V.

Transistor TR1 generates a current that discharges the capacitor C1 depending on the light sensing control voltage VMS and the intensity and wavelength of the light. In this case, the driving voltage VSS is a voltage belonging to a range of 0 V to −10 V, and may be, for example, −5 V. In addition, the gate-source voltage of transistor TR1 becomes VMS-VSS, and the current flowing to the transistor TR1 is controlled depending on the intensity and wavelength of the light. The light sensing control voltage VMS may be a voltage belonging to a range of −5 V to +5 V depending on the current size required for the transistor TR1.

Then, the current flowing from the transistor TR1 to the node N2 discharges the capacitor C1, thereby reducing the voltage of the node N1. That is, the gate voltage of the transistor TR3 decreases depending on the intensity and wavelength of the incident light. The data voltage Vd is changed as the transistor TR1 changes the gate voltage of the transistor TR3 depending on the intensity and wavelength of the incident light. When the transistor TR4 is turned on by the first gate signal S[i], the data voltage Vd is transmitted to the data line Dj. As the gate voltage of the transistor TR3 decreases, the data voltage Vd output through the transistor TR3 may decrease.

Alternatively, the transistor TR3 may be turned on with the reset voltage Vreset and then be turned off gradually depending on the intensity and wavelength of the light.

For example, the second gate signal G[i] becomes the low level such that the transistor TR2 is turned on and the reset voltage Vreset is supplied to the node N1. Then, the transistor TR3 is turned on. At this time, the reset voltage Vreset is a voltage belonging to a range of 0 V to −10 V, for example, may be −5 V.

The transistor TR1 generates the current that charges the capacitor C1 depending on the light sensing control voltage VMS and the intensity and wavelength of the light. In this case, the driving voltage VSS) is a voltage belonging to a range of 0 V to 10 V and may be, for example, 3 V. In addition, the gate-source voltage of transistor TR1 becomes VMS-Vreset, and the current flowing through the transistor TR1 is controlled depending on the intensity and wavelength of the light. The light sensing control voltage VMS may be a voltage belonging to a range of −5 V to 5 V depending on the current size required for the transistor TR1.

Then, the current flowing to the node N1 from the transistor TR1 charges the capacitor C1, and the voltage of the node N1 increases. That is, the gate voltage of the transistor TR3 increases depending on the intensity and wavelength of the incident light. The data voltage Vd is changed as the transistor TR1 changes the gate voltage of the transistor TR3 depending on the intensity and wavelength of the incident light. When the transistor TR4 is turned on by the first gate signal S[i], the data voltage Vd is transmitted to the data line Dj. As the gate voltage of the transistor TR3 increases, the data voltage output through the transistor TR3 may decrease.

Since the sensor pixel according to the exemplary embodiment uses amorphous silicon TFT as a photosensor TFT, a process step is reduced compared to when using a pin photodiode.

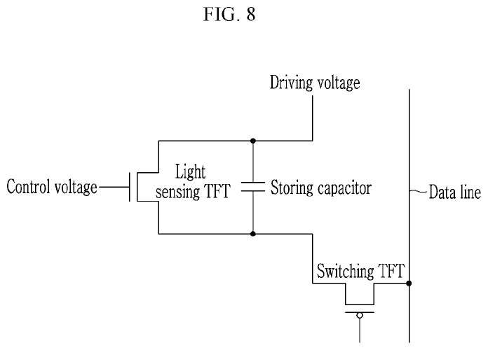

FIG. 8 is a view showing a conventional passive pixel.

As shown in FIG. 8, a conventional passive pixel includes one light sensing TFT, a storing capacitor, and a switching TFT.

The sensor pixel according to the exemplary embodiment amplifies the signal in the pixel, so compared to the passive pixel, the sensor pixel may be sensed with smaller light intensity or a shorter exposure time.

The sensor pixel according to the exemplary embodiment charges the capacitor C1 for the period from the time at which the gate of transistor TR3 is initialized by the reset voltage Vreset until the transistor TR4 is turned on by the first gate signal. Then, compared with the passive pixel of FIG. 8 charging the storing capacitor during one frame, it is less affected by the light reaction speed of the light sensing TFT.

Also, for the same reason as above, the capacitance of the capacitor C1 may be small compared to the passive pixel of FIG. 8, such that it is easy to reset the charge accumulated in the capacitor C1.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

1: image sensor
10: sensor panel
20: gate driving circuit
30: timing control circuit
40: sensor signal readout circuit
50: light source

What is claimed is:

1. A sensor pixel comprising:
a first transistor for light sensing;
a second transistor including one terminal connected to one terminal of the first transistor and the other terminal to which a reset voltage is transmitted;
a third transistor including a gate connected to one terminal of the first transistor and one terminal connected to the other terminal of the first transistor; and
a fourth transistor connected between the other terminal of the third transistor and a data line.

2. The sensor pixel of claim 1, wherein
the first transistor is formed of amorphous silicon.

3. The sensor pixel of claim 1, further comprising
a capacitor for fixing a gate voltage of the third transistor.

4. The sensor pixel of claim 3, wherein
the capacitor includes
a parasitic capacitor of the third transistor, a first capacitor formed between a gate and one terminal of the third transistor, a second capacitor formed between the gate of the third transistor and the gate of the first transistor, a third capacitor formed between the gate of the third transistor and the other terminal of the second transistor, or at least two among the parasitic capacitor and the first to third capacitors.

5. The sensor pixel of claim 1, wherein
the fourth transistor is switched depending on a first gate signal, the second transistor is switched depending to a second gate signal, and enable timing of the second gate signal precedes enable timing of the first gate signal.

6. An image sensor comprising:
a sensor panel including a plurality of sensor pixels, and a plurality of first gate lines, a plurality of second gate lines, and a plurality of data lines connected to the plurality of sensor pixels;
a gate driving circuit supplying a plurality of first gate signals and a plurality of second gate signals corresponding to the plurality of first gate lines and the plurality of second gate lines; and
a sensor signal readout circuit receiving a plurality of data signals from the plurality of sensor pixels through the plurality of data lines,
wherein each of the plurality of pixel sensors is implemented by a sensor pixel,
wherein the sensor pixel comprises:
a first transistor for light sensing;
a second transistor including one terminal connected to one terminal of the first transistor and the other terminal to which a reset voltage is transmitted;
a third transistor including a gate connected to one terminal of the first transistor and one terminal connected to the other terminal of the first transistor; and
a fourth transistor connected between the other terminal of the third transistor and a data line.

7. The image sensor of claim 6, wherein
a phase difference exists between the first gate signal and the second gate signal corresponding to the plurality of sensor pixels disposed in the same row.

8. The image sensor of claim 7, wherein
the enable timing of the second gate signal precedes the enable timing of the first gate signal.

9. The image sensor of claim 6, wherein
the gate driving circuit includes:
a first gate driving unit generating a plurality of first gate signals; and
a second gate driving unit generating a plurality of second gate signals.
